(19) United States
(12) Patent Application Publication
(10) Pub. No.: US 2007/0087289 A1
(43) Pub. Date: Apr. 19, 2007

(54) Printing form and method for imaging a printing form

(75) Inventor: Dirk Probian, Gablingen/Luetzelburg (DE)

Correspondence Address: CROWELL & MORING LLP;INTELLECTUAL PROPERTY GROUP, P.O. BOX 14300, WASHINGTON, DC, 20044-4300, US

(73) Assignee: MAN Roland Druckmaschinen AG, Augsburg (DE)

(21) Appl. No.: 11/529,844

(22) Filed: Sep. 29, 2006

(30) Foreign Application Priority Data
Sep. 30, 2005 (DE) 10 2005 046 863.2

(51) Int. Cl. G03F 7/00

(52) U.S. Cl. 430/302

(57) ABSTRACT

A printing form and method for imaging a printing form, in particular a printing sleeve or printing plate, is disclosed. The printing form, having a printing form carrier and a polymer layer which is applied to the printing form carrier, can be imaged and can be erased, it being possible for the polymer layer to be applied by a photocatalytic route and/or a photochemical route, and it being possible for the polymer layer to be erased by the action of electromagnetic radiation and/or by the action of heat and/or by the action of at least one solvent and/or by abrasive removal.

This application claims the priority of German Patent Document No. 10 2005 046 863.2, filed Sep. 30, 2005, the disclosure of which is expressly incorporated by reference herein.

### BACKGROUND AND SUMMARY OF THE INVENTION

The invention relates to a printing form and method for imaging the printing form.

During printing with a printing form, in principle a distinction is drawn between printing processes which operate either with a printing form which can be written once or with a rewritable printing form. Printing processes which use rewritable printing forms are also summarized under the keyword “computer to press/direct imaging”. The present invention relates to a rewritable printing form.

Under the product description “DICOweb”, the applicant markets digital presses which operate with rewritable and erasable printing forms. When printing forms using DICOweb technology are used, a printing form carrier, preferably a basic printing form cylinder, is subjected to an erasure step and an imaging step. Imaging of the printing form is possibly followed by fixing and conditioning of the imaged printing form. The basic principles of the DICOweb technology are known from “Handbuch der Printmedien” [Printing Media Manual], Helmut Kipphan, pages 674-680, 2000, Springer-Verlag.

During the imaging of a printing form in accordance with the DICOweb technology, an imaging material is applied to the printing form carrier with the aid of a thermal transfer process and has to be removed in order to erase the same. In particular, the application and removal of the imaging material is relatively complicated in process engineering terms, so that there is a need for rewritable and erasable printing forms in which, in order to image and erase the same, imaging material neither has to be applied nor removed.

Taking this as its starting point, the present invention is based on the problem of providing a novel type of rewritable printing form. This problem is solved by the printing form according to the present invention. The printing form according to the invention has a printing form carrier and a polymer layer which is applied to the printing form carrier, can be imaged and can be erased, it being possible for the polymer layer to be applied by a photocatalytic route and/or a photochemical route, and it being possible for the polymer layer to be erased by the action of electromagnetic radiation and/or by the action of heat and/or by the action of at least one solvent and/or by abrasive removal.

The printing form according to the invention has a polymer layer that can be erased and imaged, which is applied to the printing form carrier of the printing form according to the invention. The imaging of the printing form is carried out by photocatalytic or photochemical manipulation of the polymer layer, so that no imaging material has to be applied to the printing form in order to image the printing form. In this way, the imaging of rewritable and erasable printing forms is simplified as compared with the prior art. The polymers of the imaged polymer layer, manipulated by such photocatalytic or photochemical processes, can, moreover, be reorganized and therefore erased, so that, following the erasure, re-imaging or new imaging of the printing form can be carried out. In this case, the imaged polymer layer is preferably erased by means of electromagnetic radiation and/or by the action of heat.

According to a preferred embodiment of the invention, the polymer layer comprises a large number of dipole-like polymer brushes having a hydrophilic, and therefore, water-carrying end and a hydrophobic, and therefore, ink-carrying end, it being possible for the polymer brushes to be oriented by means of image-data-based irradiation with UV light and therefore for the polymer layer to be imaged, and it being possible for the polymer layer to be erased by the action of electromagnetic radiation and/or by the action of heat and/or by the action of at least one solvent.

According to a further preferred development of the invention, the polymer layer is formed as a layer that is ultrahydrophobic, and therefore, ink-carrying, it being possible for the polymer layer to be nanostructured by means of image-data-based laser irradiation and therefore transferred section by section into a hydrophilic, and therefore, water-carrying layer, and it being possible for the nanostructured polymer layer to be erased by means of abrasive removal.

Preferred developments of the invention emerge from the following description.

### BRIEF DESCRIPTION OF THE DRAWINGS

Exemplary embodiments of the invention, without being restricted thereto, will be explained in more detail below with reference to the drawings, in which:

FIG. 1 shows a schematic illustration of a rewritable and erasable printing form according to the invention in accordance with a first exemplary embodiment of the invention, in erased form;

FIG. 2 shows a detail of the printing form from FIG. 1;

FIG. 3 shows the printing form according to the invention from FIG. 1 in imaged form;

FIG. 4 shows a schematic illustration of a rewritable and erasable printing form according to the invention in accordance with a second exemplary embodiment of the invention, in erased form; and

FIG. 5 shows the printing form according to the invention from FIG. 4 in imaged form.

### DETAILED DESCRIPTION OF THE DRAWINGS

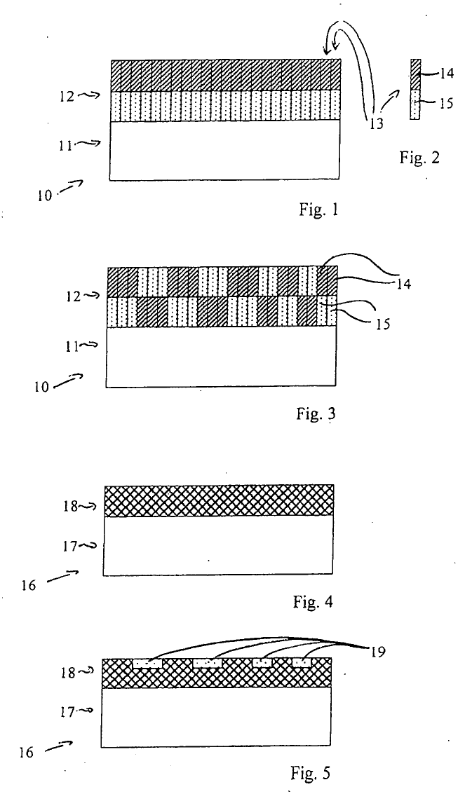

FIGS. 1 to 3 show a first exemplary embodiment of a rewritable and erasable printing form 10 according to the invention, the printing form 10 of the exemplary embodiment according to FIGS. 1 to 3 having a printing form carrier 11 and a polymer layer 12 applied to the printing form carrier 11.

The polymer layer 12 in the exemplary embodiment of FIGS. 1 to 3 is formed by a large number of polymer brushes 13 (see FIG. 2), each of the polymer brushes 13 having a hydrophilic or water-carrying end 14 and a hydrophobic or ink-carrying layer 15. Accordingly, the polymer brushes 13 are formed in the manner of dipoles, a first pole being formed by the hydrophilic, and therefore, water-carrying end 14, and a second pole being formed by the hydrophobic, and therefore, ink-carrying end 15. FIG. 1 shows the polymer layer 12 of the printing form 10 according to the invention in a state in which all the polymer brushes 13 are oriented in the same way. In the exemplary embodiment of FIG. 1, the polymer layer 12 is therefore universally hydrophilic, and therefore, water-carrying in its outer surface.

The polymer layer 12 formed from the dipole-like polymer brushes 13 can be imaged by a photocatalytic route or photochemical route, specifically by means of exposure of the polymer brushes 13, specifically in such a way that the orientation of the polymer brushes 13 is changed. Thus, FIG. 3 shows a printing form 10 imaged by irradiating the polymer layer 12, the hydrophobic or ink-carrying ends 15 of the polymer brushes 13 reaching the outer surface of the polymer layer 12 and therefore of the printing form 10 in the irradiated sections. The irradiation of the polymer brushes 13 of the polymer layer 12 is carried out on the basis of image data, for this purpose the printing form 10 or the polymer layer 12 being irradiated in the regions of the same in which the same is intended to be ink-carrying for the purpose of printing. The image-data-based irradiation of the polymer layer 12 is preferably carried out with UV light, preferably with UV laser light.

A printing form 10 or polymer layer 12 of a printing form 10 imaged by irradiation can also be erased, the erasure preferably being carried out by the action of electromagnetic radiation on the polymer layer 12. The erasure of an imaged polymer layer 12 can also be carried out by heat acting on the same.

It is also possible to erase an imaged printing form 12 by means of the action of at least one solvent. It is also possible to imagine using a plurality of these erasure methods in combination to erase an imaged polymer layer 12.

Following the erasure, the printing form 10 is once more present in the orientation illustrated in FIG. 1, so that new imaging of the printing form 10 can be carried out by means of image-data-based irradiation of the polymer layer 12 and therefore of the polymer brushes 13.

The dipole-like polymer brushes 13 are preferably PI/P2VP polymer systems or poly[styrene-co-2(4-vinylphenyl)indene]/P2VP polymer systems. Polymer brushes of such polymer systems can be oriented well by irradiation with UV light, so that hydrophobic or ink-carrying and hydrophilic or water-carrying sections can specifically be achieved on the outer surface of a polymer layer in this way.

According to an advantageous development, it is possible to incorporate or embed the polymer brushes 13 in an ultrahydrophobic polymer. Given a combination of switchable polymer brushes with an ultrahydrophobic polymer, the ability to switch the polymer brushes by means of UV irradiation of the same can be improved in such a way that relatively low switching amplitudes are sufficient to orient the dipole-like polymer brushes specifically during the irradiation in order to provide a desired printing form.

The ultrahydrophobic carrier polymer can be, for example, PTFE (polytetrafluoroethylene), in which dipole-like polymer brushes preferably made of carboxyl-terminated poly(styrene-co-2,3,4,5,6-pentafluorostyrene) and carboxyl-terminated poly(2-vinylpyridine) are embedded.

A second exemplary embodiment of a rewritable and erasable printing form according to the invention is shown by FIGS. 4 and 5, the printing form 16 of this exemplary embodiment again having a printing form carrier 17 and a polymer layer 18 applied to the printing form carrier 17. In the exemplary embodiment of FIGS. 4 and 5, the polymer layer 18 is a polymer layer of ultrahydrophobic, and therefore, ink-carrying polymer, in particular of PTFE (polytetrafluoroethylene), which, following plasma etching in a low-pressure oxygen plasma, exhibits ultrahydrophobic properties. Such an ultrahydrophobic polymer layer 18 can be nanostructured section-by-section by means of photocatalytic or photochemical processes, in particular by means of image-data-based laser irradiation, so that the originally ultrahydrophobic polymer layer 18 becomes hydrophilic, and therefore, water-carrying in the irradiated sections 19 close to the surface. In order to erase the polymer layer 18, it is merely necessary for an outer region of the same to be removed abrasively, so that new imaging of the polymer layer 18 can then be carried out.

In the spirit of the present invention, imaging of printing forms without any application of imaging material is possible. A polymer layer of the printing form according to the invention is imaged on the basis of image data by means of photocatalytic or photochemical processes. The printing form according to the invention can either be a printing sleeve or a printing plate.

### LIST OF REFERENCE SYMBOLS

10 Printing form
11 Printing form carrier
12 Polymer layer
13 Polymer brush
14 Hydrophilic or water-carrying end
15 Hydrophobic or ink-carrying end
16 Printing form
17 Printing form carrier
18 Polymer layer
19 Section

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A printing form, in particular a printing sleeve or a printing plate, having a printing form carrier and a polymer layer which is applied to the printing form carrier, wherein the printing form is imageable and erasable, wherein the polymer layer is applied by a photocatalytic process and/or a photochemical process, and wherein the polymer layer is erased by electromagnetic radiation and/or by heat and/or by at least one solvent and/or by abrasive removal.

2. The printing form according to claim 1, wherein the polymer layer includes a plurality of dipole-like polymer brushes each having a hydrophilic water-carrying end and a hydrophobic ink-carrying end, wherein the polymer brushes are orientable and, as such, the polymer layer is imageable by means of image-data-based irradiation with light.

3. The printing form according to claim 2, wherein the polymer brushes are orientable by means of image-data-based irradiation with UV laser light.

4. The printing form according to claim 2, wherein the polymer brushes are comprised of PI/P2VP polymers.

5. The printing form according to claim 2, wherein the polymer brushes are comprised of poly[styrene-co-2(4-vinylphenyl)indene]/P2VP polymers.

6. The printing form according to claim 2, wherein the polymer brushes are embedded in an ultrahydrophobic polymer.

7. The printing form according to claim 6, wherein the ultrahydrophobic polymer is formed as PTFE (polytetrafluoroethylene), in which dipole-like polymer brushes made of carboxyl-terminated poly(styrene-co-2,3,4,5,6-pentafluorostyrene) and carboxyl-terminated poly(2-vinylpyridine) are embedded.

8. The printing form according to claim 1, wherein the polymer layer is formed as a layer that is ultrahydrophobic ink-carrying, and wherein nanostructured sections of the polymer layer are irradiated by means of image-data-based laser irradiation and wherein the irradiated sections are hydrophilic water-carrying.

9. The printing form according to claim 8, wherein the nanostructured sections of the polymer layer are erasable by means of abrasive removal.

10. A printing form, comprising:
a printing form carrier; and
an imageable and erasable polymer layer applied to the printing form carrier.

11. The printing form according to claim 10, wherein the polymer layer includes a plurality of polymer brushes each having a hydrophilic water-carrying end and a hydrophobic ink-carrying end.

12. The printing form according to claim 11, wherein when the polymer layer is imaged the hydrophilic water-carrying ends and the hydrophobic ink-carrying ends of the plurality of polymer brushes are non-uniformly oriented.

13. The printing form according to claim 11, wherein when the polymer layer is erased the hydrophilic water-carrying ends and the hydrophobic ink-carrying ends of the plurality of polymer brushes are uniformly oriented.

14. The printing form according to claim 11, wherein the polymer layer is imageable by an irradiation process.

15. A method for imaging a printing form, comprising the steps of:
irradiating a polymer layer of a printing form carrier of the printing form, wherein polymers of the polymer layer are oriented in a non-uniform orientation by the irradiating step.

16. The method according to claim 15, further comprising the step of erasing the printing form by orienting the polymers of the polymer layer in a uniform orientation.

17. The method according to claim 15, wherein the polymer layer includes a plurality of polymer brushes each having a hydrophilic water-carrying end and a hydrophobic ink-carrying end.

18. The method according to claim 17, wherein when the polymers of the polymer layer are oriented in the non-uniform orientation, the hydrophilic water-carrying ends and the hydrophobic ink-carrying ends of the plurality of polymer brushes are non-uniformly oriented.

19. The method according to claim 16, wherein the polymer layer includes a plurality of polymer brushes each having a hydrophilic water-carrying end and a hydrophobic ink-carrying end and wherein when the printing form is erased the hydrophilic water-carrying ends and the hydrophobic ink-carrying ends of the plurality of polymer brushes are uniformly oriented.

20. The method according to claim 15, wherein the irradiating step includes a photocatalytic process or a photochemical process.
